(19) United States
(12) Patent Application Publication
(10) Pub. No.: US 2024/0290574 A1
(43) Pub. Date: Aug. 29, 2024

(54) METHOD FOR IMAGING WITH A SCANNING ELECTRON MICROSCOPE AND SCANNING ELECTRON MICROSCOPE FOR CARRYING OUT THE METHOD

(71) Applicant: Carl Zeiss SMT GmbH, Oberkochen (DE)

(72) Inventors: Daniel Fischer, Dresden (DE); Bernd Schindler, Aalen (DE); Andreas Schmaunz, Oberkochen (DE)

(21) Appl. No.: 18/657,195

(22) Filed: May 7, 2024

Related U.S. Application Data
(63) Continuation of application No. PCT/EP2022/081793, filed on Nov. 14, 2022.

(30) Foreign Application Priority Data
Nov. 18, 2021 (DE) 10 2021 212 978.1

(51) Int. Cl. H01J 37/28; H01J 37/20; H01J 37/26

(52) U.S. Cl. CPC H01J 37/28; H01J 37/20; H01J 37/265

(57) ABSTRACT

In the context of imaging with a scanning electron microscope, a sample to be imaged is first positioned in a vacuum chamber of the scanning electron microscope (SEM), such that an imaging field of the SEM arrives at a section of the sample to be imaged. Water is added to the vacuum chamber, such that the water is precipitated as an H₂O layer on the sample in the region of the imaging field. The sample in the vacuum chamber is then cooled to a temperature below −10° C. Then a sample cleaning operation is performed with the aid of at least one electron cleaning scan within a cleaning field within which the imaging field lies. The H2O layer is removed during the cleaning scan. Then the imaging field is imaged with the aid of an electron imaging scan after the at least one cleaning scan has ended. The result is an imaging method in which a sample surface of the sample to be imaged in the imaging of an imaging field is reliably clean.

### CROSS-REFERENCE TO RELATED APPLICATION

The present application is a continuation of, and claims benefit under 35 USC 120 to, international application No. PCT/EP2022/081793, filed Nov. 14, 2022, which claims benefit under 35 USC 119 of German Application No. 10 2021 212 978.1, filed Nov. 18, 2021. The entire disclosure of each of these applications is incorporated by reference herein.

### FIELD

The field relates to a method of imaging with a scanning electron microscope. The field further relates to a scanning electron microscope (SEM) for performance of the method.

### BACKGROUND

Scanning electron microscopes and imaging methods for the purpose are known, for example, from EP 1 362 361 B1 and U.S. Pat. No. 5,319,207. US 2010/0126255 A1 discloses ice layers in systems that work with charged particles, and methods for the purpose. US 2013/0288182 A1 discloses an electron beam processing operation utilizing condensed ice. WO 2007/044035 A2 discloses structuring via energetically stimulated local removal of resublimed gas layers and chemical solid-state reactions that are created with such layers. US 2004/0140298 A1 discloses a substrate cleaning operation with the aid of an ice layer. WO 89/10803 A1 discloses a method of cleaning surfaces and fluids. JP 11031673 A discloses an apparatus and a method for substrate cleaning. A device for ice lithography is known from the journal article “An ice lithography instrument” by A. Han et al., Rev. Sci. Instrum. 82, 065110 (2011).

For assurance of good image quality, a clean surface of a sample to be imaged is desirable.

### SUMMARY

The present disclosure seeks to provide an imaging method for scanning electron microscopy such that a sample surface of the sample to be imaged in the imaging of an imaging field is reliably clean.

In an aspect, the disclosure provides a method of imaging with a scanning electron microscope comprising: positioning a sample to be imaged in a vacuum chamber of the scanning electron microscope such that an imaging field of the SEM arrives at a section of the sample to be imaged; adding water to the vacuum chamber such that the water is precipitated as an H₂O layer on the sample in the region of the imaging field; cooling the sample in the vacuum chamber to a temperature below −10° C.; performing a sample cleaning operation with the aid of at least one electron cleaning scan within a cleaning field within which the imaging field lies, with removal of the H₂O layer during the cleaning scan; imaging the imaging field with the aid of an electron imaging scan after the at least one cleaning scan has ended, wherein a resultant ice layer on the sample in the region of the imaging field has a thickness in the range between 1 nm and 10 nm.

It has been recognized in accordance with the disclosure that a combination of adding of water and cooling makes it possible first to bind contamination on the sample surface to be imaged in the water/ice layer and then to remove it with the aid of the electron cleaning scan. For example, hydrocarbon compounds that contaminate the sample surface can be removed efficiently in this way. Sample cooling has the desirable secondary effect of inhibiting or completely preventing migration of carbon contamination.

An ice layer thickness in the range between 1 nm and 10 nm can be removed quickly with the aid of the electron cleaning scan, such that the cleaning does not undesirably take up valuable measurement time. It has been found that such a thin ice layer leads to a sufficient cleaning effect in the performance of the sample cleaning operation.

The SEM may be a ULV (ultralow voltage) SEM. The SEM may be run in reflection and/or in transmission.

Methods disclosed herein can give better cleaning results than methods of reducing a contaminating effect that are discussed for STEM microscopes in the journal article “Contamination mitigation strategies for scanning transmission electron microscopy” by D. Mitchell et al., Micron, 73 36-46, 2015.

During the addition of water and during the electron cleaning scan, binding of the contamination can be accomplished using chemical processes that are described in association with the cleaning of optical surfaces in WO 2008/107 166 A1 and WO 2008/061 690 A1.

In some embodiments, the sample is cooled to a temperature below −100° C. Such sample cooling temperatures have been found to be useful in practice. The cooling temperature may be in the range between +−100° C. and −200° C., and especially in the range between −140° C. and −200° C.

In some embodiments, water is added until there is a partial H₂O pressure in the vacuum chamber in the region of 10⁻³ mbar. Such addition of water results in a sufficiently thick H₂O layer on the sample surface to be imaged. The partial H₂O pressure can be monitored via a pressure sensor in the vacuum chamber. For example, controlled addition of water is possible as a function of the pressure measured in the vacuum chamber. The partial H₂O pressure may be in the range between 1 and 10×10⁻³ mbar.

In some embodiments, the sample is cooled even before or during the addition of water such that the H₂O layer is precipitated as the ice layer on the sample in the course of addition. Such cooling even before or during the addition of water has been found to be useful since the added water in that case is precipitated straight away as an ice layer on the sample and adheres reliably thereon. Alternatively, the sample may also be cooled only after the addition of water.

In some embodiments, the resultant ice layer on the sample in the region of the imaging field has a thickness in the range between 1 nm and 6 nm. Such ice layer thicknesses have been found to be useful in practice. The ice layer thickness may, for example, be in the region of 2 nm or in the region of 5 nm.

In some embodiments, the sample cleaning operation involves conducting more than one hundred cleaning scans. Such a number of cleaning scans results in efficient cleaning of the cleaning field without undesirable persistence of ice residues therein. In the sample cleaning operation, one hundred to one thousand cleaning scans may be conducted, for example around 500 cleaning scans.

In some embodiments, in the sample cleaning operation, there is a dwell time of a cleaning electron beam for each scan pixel in the range between 100 ns and 1 μs. Such a dwell time of a cleaning electron beam has been found to be useful for an efficient cleaning operation. The dwell time may be in the range between 400 ns and 600 ns.

In some embodiments, the cleaning electrons in the sample cleaning operation have an energy in the range between 100 eV and 1000 eV. Such cleaning electron energies have been found to be useful for the cleaning operation. The cleaning electrons may have an energy in the range between 500 eV and 800 eV.

Depending on the application of the SEM, the cleaning energy of the electrons may be smaller or greater than the imaging energy.

In some embodiments, the cooling of the sample also cools a cold finger in the vacuum chamber. Such cold finger cooling offers a precipitation surface for contamination, without disruption by the contamination. For example, a contamination parted from the sample surface during the cleaning step can be precipitated on the cold finger.

In an aspect, the disclosure provides a scanning electron microscope for performance of a method according to the disclosure. The scanning electron microscope includes: an electron beam source having an electron beam scanning unit; a sample holding stage which is movable with respect to an electron beam from the electron beam source; a vacuum chamber in which the sample holding stage is mounted; a water addition nozzle for addition of water to the vacuum chamber; a cooling device for cooling of the sample holding stage; and a central open-loop/closed-loop control device. The benefits of such an SEM correspond to those that have already been elucidated above with reference to the imaging method. The SEM may be a ULV SEM.

The central open-loop/closed-loop control device is in signal connection with the components to be actuated and with measurement components, especially a pressure sensor in the vacuum chamber.

The SEM can include a valve in the water addition nozzle and a pressure sensor in the vacuum chamber having signal connection to the open-loop/closed-loop control unit. The benefits of such an SEM correspond to some of those that have already been elucidated above. Controlled addition of water can be assured.

The SEM can include a cold finger disposed in the vacuum chamber. The benefits of such a cold finger correspond to some of those that have already been elucidated above.

Embodiments of the disclosure are discussed below with reference to the drawings.

### BRIEF DESCRIPTION OF THE DRAWINGS

The figures show:

FIG. 1 a schematic diagram of a scanning electron microscope;

FIG. 2 a detail from a sample surface to be analyzed by the scanning electron microscope, where a section of the detail shown in the form of a rectangular cleaning field has been cleaned, where a contaminated sample surface surrounding the cleaning field is visible outside the cleaning field, offset in a gray shade;

FIG. 3 a detail enlargement of the sample surface according to FIG. 2 after imaging of the imaging field with the aid of an electron imaging scan by the scanning electron microscope; and

FIG. 4 a flow diagram of an imaging method conducted with the scanning electron microscope according to FIG. 1.

### DETAILED DESCRIPTION

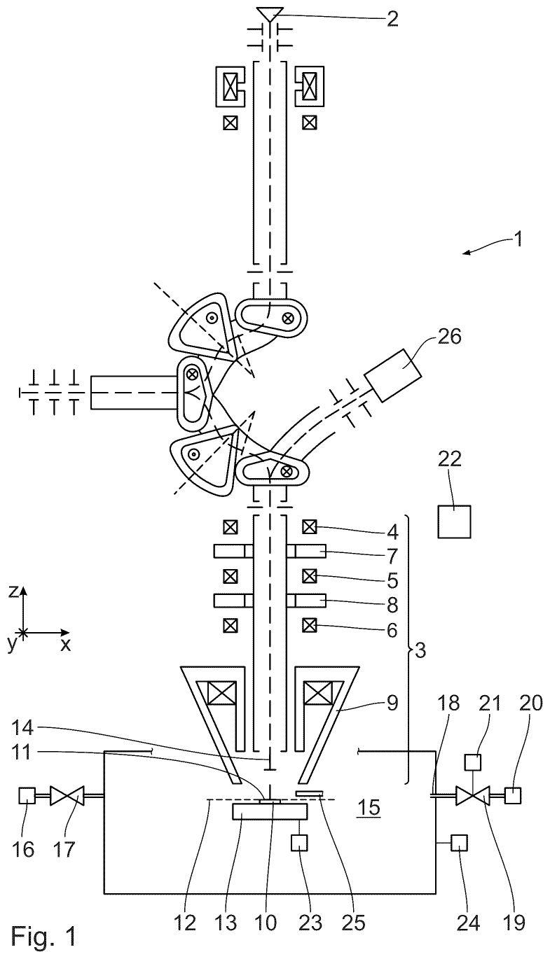

By way of elucidation of positional relationships, a Cartesian xyz coordinate system is utilized hereinafter. x direction runs to the right in FIG. 1. y direction runs into the plane of the drawing at right angles thereto in FIG. 1. z direction runs upward in FIG. 1.

FIG. 1 shows a schematic of the main components of a scanning electron microscope (SEM) 1. A beam generator, beam guide and beam detection of the SEM 1 is known in principle, for example, from EP 1 362 361 B1 and will therefore not be elucidated in detail. This publication also gives elucidations of components of FIG. 1 that are not described in detail here.

The SEM 1 has an electron beam source 2 and an electron beam scanning unit 3, including deflection systems 4, 5 and 6, and intermediate twelve-pole elements 7, 8, and an objective 9. A sample 10 to be analyzed by the SEM 1 has a surface 11 disposed in an imaging plane 12 of the objective 9. The imaging plane 12 runs parallel to the xy plane. The sample 10 is held by a sample holding stage 13, also referred to as sample holder.

Using the electron beam scanning unit 3 and/or using a scanning drive of the sample holding stage 13, the sample 10 is movable in x direction and y direction with respect to an electron beam 14 from the electron beam source 2 for scanning of the sample surface 11 to be examined.

The sample holding stage 13 together with the sample 10 is disposed in a vacuum chamber 15 of the SEM 1. The vacuum chamber 15 is indicated only as a section in FIG. 1. The vacuum chamber 15 is evacuated using a vacuum pump 16 connected to the vacuum chamber 15 via a valve 17.

The SEM 1 has a water addition nozzle 18 for addition of water to the vacuum chamber 15. The water addition nozzle 18 is in fluid connection to a water reservoir 20 via a valve 19. The valve 19 is controllable via a valve controller 21 for opening/closing. An opening width of the valve 19 can be defined, especially continuously, via the valve controller 21. The valve controller 21 and further open-loop and closed-loop control components of the SEM 1 are in signal connection, in a manner not illustrated in detail, with a central open-loop/closed-loop control unit 22 of the SEM 1.

The sample holding stage 13 and hence the sample 10 are cooled using a cooling device 23 of the SEM 1, which is in thermal contact with the sample holding stage 13. The cooling device 23 is in turn in signal connection to the open-loop/closed-loop control unit 22.

The SEM 1 also has a pressure sensor 24 for measuring a chamber pressure in the vacuum chamber 15. The pressure sensor 24 is in turn in signal connection to the central open-loop/closed-loop control unit 22.

In the vacuum chamber 15, depending on the design of the SEM 1, there may be disposed at least one cold finger 25, indicated schematically in FIG. 1 without further retaining structure. The cold finger 25 may be retained on the housing of the objective 9. The cold finger 25 is in thermal contact with the cooling device 23, in a manner which is not shown.

A detector 26 serves to detect secondary electrons and backscattered electrons that emanate from the sample 10.

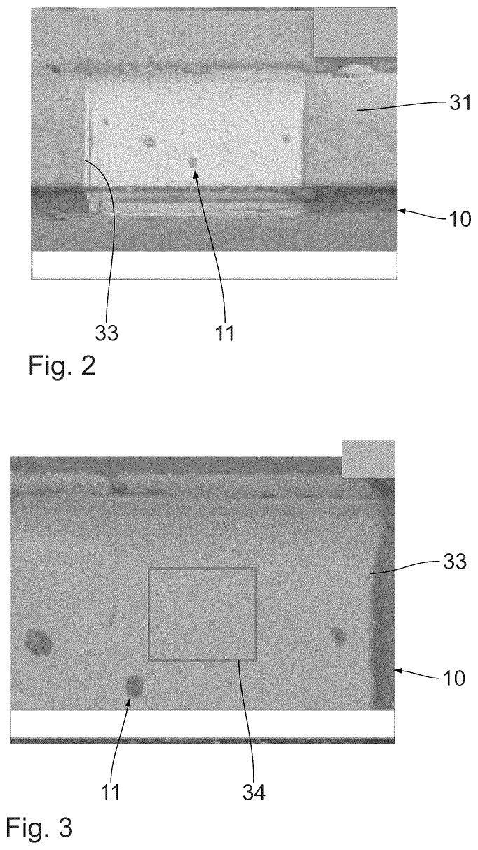

With reference to FIGS. 2 to 4, there follows a description of a method of imaging with the SEM 1.

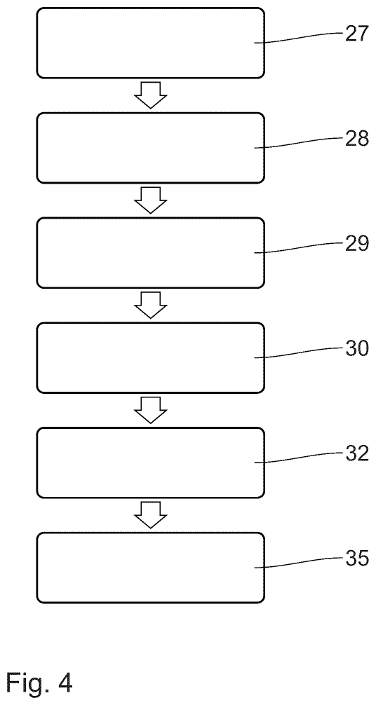

In a positioning step 27 (cf. FIG. 4), the sample 10 to be imaged is positioned in the vacuum chamber 15 of the SEM 1, such that an imaging field of the SEM 1 in the imaging plane 12 arrives at a section to be imaged on the surface 11 of the sample 10. This is done via sample adjustment using the sample holding stage 13 by translation along the x and y coordinates and if desired also along the z coordinate, and if desired via tilting of the sample 10 about tilt axes parallel to the x axis and/or parallel to the y axis.

In a first cooling step 28, the sample 10 is then cooled down to a temperature of −140° C. or lower. This is done using the cooling device 23. In general, a minimum temperature of the sample 10 after the first cooling step 28 is below −10° C. or −100° C.

In an addition step 29, water is then added to the vacuum chamber 15, such that the water is precipitated as a water layer on the sample 10 in the region of the imaging field.

The water is added by actuating the addition valve 19 with the valve controller 21. The water is added until there is a partial water pressure in the vacuum chamber 15 in the region of at most 5×10⁻³ mbar, for example in the region of 1×10⁻³ mbar. The water can be added under closed-loop control in accordance with measurement results from the pressure sensor 24. A corresponding control routine may be executed in the central open-loop/closed-loop control unit 22.

The addition step 29 is followed by a further cooling step 30 for cooling of the sample 10 to a target temperature, which may, for example, be −160° C. and is regularly not lower than −200° C. The target temperature is regularly less than-10° C. This further cooling step 30 is effected via the cooling device 23.

Because of the addition of water and because of the sample cooling, an ice layer 31 (cf. FIG. 2) is precipitated on the surface 11 of the sample 10. A thickness of the ice layer 31 may be in the region of 1 nm and 10 nm and may, for example, be 2 nm or 5 nm. The ice layer 31 binds carbon contamination present on the surface 11 of the sample 10.

Conclusion of cooling is followed by a cleaning step 32. A cleaning operation is conducted here on the sample 10 with the aid of an electron cleaning scan within a cleaning field 33 (cf. FIG. 2), in which the imaging field (cf. imaging field 34 in FIG. 3) lies. During this cleaning scan, which is actuated via the electron deflection system of the SEM 1, the water layer is removed with the carbon contamination bound therein.

FIG. 2 shows the situation on conclusion of the cleaning step 32. The clean surface 11 of the sample 10 is within the cleaning field 33. Outside the cleaning field 33, the ice layer 31 and the carbon contamination on the surface 11 are still present.

The cleaning field 33 is roughly rectangular because of the line-by-line and column-by-column scanning in the electron cleaning scan.

In the cleaning step 32, more than one hundred sequential cleaning scans are conducted, during which the entire cleaning field 33 is scanned with the electron cleaning beam.

In the cleaning operation, the electrons incident on the cleaning field 33 have an energy in the range between 100 eV and 1000 eV, especially in the range between 500 eV and 800 eV.

The cleaning electron energy is, for example, less than in the actual sample imaging by the SEM 1. This electron imaging energy may be in the region of a few keV to a few tens of keV, for example in the range between 5 keV and 50 keV, for example 15 keV. Alternatively, the imaging electrons from the electron beam 14 may also have much smaller energies of less than 1 keV. The SEM 1 is then utilized as ULV (ultralow voltage) SEM. A typical imaging electron energy may be in the range between 10 eV and 50 eV, for example 30 eV.

In the sample cleaning operation in the cleaning step 32, a dwell time of the cleaning electron beam 14 for each scan pixel in the scanning operation is in the range between 100 ns and 1 μs. Such a scan pixel may have an area of about 1 nm×1 nm on the surface 11. This dwell time may, for example, be 400 ns or 500 ns.

In the cooling steps 28, 30, the cold finger 25 in the vacuum chamber 15 may also be cooled. A contamination/water mixture is then precipitated on the cold finger 25, such that the contamination is kept away from the surface 11 of the sample 10, especially in the region of the imaging field 34 and also in the region of the rest of the cleaning field.

The cleaning step 32 is followed, in an imaging step 35, by imaging of the imaging field 34 with the aid of an electron imaging scan, in which case the electrons of the electron beam 14 have higher imaging energy compared to the cleaning energy.

FIG. 3 shows a detail enlargement of the surface 11 of the sample 10 after performance of the imaging step 35, in which a greater number of imaging scans has in turn been conducted in the imaging field 34. Even after the imaging step 35, the surface 11 within the cleaning field 33 is still clean and free of carbon contamination. Nor does a comparison between the surface impression within the imaging field 34 on the one hand and outside the imaging field 34 but still within the cleaning field 33 on the other hand show any difference in quality, and so it is clear that no surface alteration has taken place during the imaging step 35. During the cleaning step 32, complete removal of the ice layer 31 including the carbon contamination bound therein has thus taken place. During the imaging step 35, no contamination in the cleaning field 33 subsequent to the cleaning step 32 has taken place within the cleaning field 33.

What is claimed is:

1. A method, comprising:
a) positioning a sample in a vacuum chamber of a scanning electron microscope (SEM) so that an imaging field of the SEM is at a section of the sample;
b) adding water to the vacuum chamber so that the water is precipitated as an H₂O layer on the sample in a region of the imaging field;
c) cooling the sample in the vacuum chamber to a temperature below −10° C., wherein b) and c) result in the H₂O layer becoming an ice layer on the sample in the region of the imaging field, the ice layer being between 1 nm and 10 nm thick;
d) removing the ice layer by scanning an electron beam generated by the SEM to perform at least one electron cleaning scan within a cleaning field within which the image field lies;
e) after d), using electrons generated by the SEM to perform an electron imaging scan to image the imaging field.

2. The method of claim 1, wherein d) removes contaminants from the sample.

3. The method of claim 1, wherein c) comprises cooling the sample to a temperature below −100° C.

4. The method of claim 1, wherein b) comprises adding water until a partial H₂O pressure in the vacuum chamber is in the region of 10⁻³ mbar.

5. The method of claim 1, wherein c) is performed before b), and the H₂O layer is precipitated as the ice layer on the sample during b).

6. The method of claim 1, wherein b) and c) are simultaneously performed, and the H₂O layer is precipitated as the ice layer on the sample during b).

7. The method of claim 1, wherein b) is performed before c), and c) causes the H₂O layer to become the ice layer.

8. The method of claim 1, wherein the ice layer is between 1 nm and 6 nm and thick.

9. The method of claim 1, wherein d) comprises using more than 100 cleaning scans.

10. The method of claim 1, wherein, during d), the electron beam has a dwell time for each scan pixel of between 100 ns and 1 μs.

11. The method of claim 10, wherein the, during d), the electrons in the electron beam have an energy of between 100 eV and 1000 eV.

12. The method of claim 1, wherein c) comprises cooling a cold finger in the vacuum chamber.

13. The method of claim 1, wherein the SEM comprises:
an electron beam source comprising an electron beam scanning unit;
a sample holding stage movable with respect to an electron beam from the electron beam source;
a vacuum chamber in which the sample holding stage is mounted;
a water addition nozzle configured to add water to the vacuum chamber;
a cooling device configured to cool the sample holding stage; and
a central open-loop/closed-loop control device.

14. The method of claim 13, wherein:
the SEM further comprises a valve in fluid communication with the water addition nozzle;
the SEM further comprises a pressure sensor configured to measure a pressure in the vacuum chamber; and
the method further comprises using the central open-loop/closed-loop control device to control the valve and the pressure sensor.

15. The method of claim 14, further comprising using the central open-loop/closed-loop control device to control: the cooling device; the sample holding stage.

16. The method of claim 13, further comprising using the central open-loop/closed-loop control device to control: the cooling device; the sample holding stage.

17. The method of claim 13, wherein the SEM further comprises a cold finger in the vacuum chamber.

18. The method of claim 1, wherein:
b) comprises adding water until a partial H₂O pressure in the vacuum chamber is in the region of 10⁻³ mbar;
c) comprises cooling the sample to a temperature below −100° C.;
d) comprises using more than 100 cleaning scans;
during d), the electron beam has a dwell time for each scan pixel of between 100 ns and 1 μs;
during d), the electrons in the electron beam have an energy of between 100 eV and 1000 eV; and
the ice layer is between 1 nm and 6 nm and thick.

19. A method of using a scanning electron microscope (SEM) comprising a vacuum chamber, the method comprising:
a) adding water to the vacuum chamber so that the water is precipitated as an H₂O layer on a sample within the vacuum chamber in a region of an imaging field of the SEM;
b) after a), cooling the sample to a temperature below −10° C. so that the H₂O layer is converted to an ice layer on the sample in the region of the imaging field, the ice layer being between 1 nm and 10 nm thick;
c) using electrons generated by the SEM to perform at least one electron cleaning scan within a cleaning field within which the image field lies to remove the ice layer; and
d) after d), using electrons generated by the SEM to perform an electron imaging scan to image the imaging field.

20. A method of using a scanning electron microscope (SEM) comprising a vacuum chamber, the method comprising:
a) cooling a sample to a temperature below −10° C., the sample being in the vacuum chamber in a region of an imaging field of the SEM;
b) after a), adding water to the vacuum chamber so that the water is precipitated as an ice layer on the sample in the region of the imaging field of the SEM;
c) using electrons generated by the SEM to perform at least one electron cleaning scan within a cleaning field within which the image field lies to remove the ice layer; and
d) after d), using electrons generated by the SEM to perform an electron imaging scan to image the imaging field.
